(19) United States
(12) Patent Application Publication
(10) Pub. No.: US 2025/0190144 A1
(43) Pub. Date: Jun. 12, 2025

(54) STORAGE DEVICE, BUFFER CHIP, AND METHOD OF OPERATING STORAGE DEVICE

(71) Applicant: Samsung Electronics Co., Ltd., Suwon-si (KR)

(72) Inventors: Hyunjin KWON, Suwon-si (KR); Youngmin JO, Suwon-si (KR); Jungjune PARK, Suwon-si (KR); Chiweon YOON, Suwon-si (KR)

(73) Assignee: Samsung Electronics Co., Ltd., Suwon-si (KR)

(21) Appl. No.: 18/947,146

(22) Filed: Nov. 14, 2024

(30) Foreign Application Priority Data
Dec. 6, 2023 (KR) 10-2023-0175934

(51) Int. Cl. G06F 3/06

(52) U.S. Cl. CPC G06F 3/0659; G06F 3/0604; G06F 3/0679

(57) ABSTRACT

Provided is a storage device that simultaneously exchanges signals with at least one storage area, the storage device including a memory controller configured to generate at least one of a chip enable signal and a one command/address signal, a buffer chip configured to receive the chip enable signal, the command/address signal, and a data signal from the memory controller, and a memory device including at least one storage area configured to perform at least one of a write operation and a read operation, based on the command/address signal and the data signal received by the buffer chip.

### CROSS-REFERENCE TO RELATED APPLICATION

This application is based on and claims priority under 35 U.S.C. § 119 to Korean Patent Application No. 10-2023-0175934, filed on Dec. 6, 2023, in the Korean Intellectual Property Office, the disclosure of which is incorporated by reference herein in its entirety.

### BACKGROUND

Inventive concepts relate to a storage device, a buffer chip, a method of operating a storage device, and more particularly, to a storage device that enables communication of a command/address signal and a data signal simultaneously with multiple storage areas included in a memory device.

Recently developed storage devices include buffer chips with channels for transmitting data signals. A buffer chip operates as an interface connecting the stacked storage areas of the memory device to implement high-capacity memory.

To increase the integration of the storage device, multiple data channels are utilized to mediate communication between data signals and command/address signals.

### SUMMARY

As described above, to increase the integration of a storage device, multiple data channels are used to mediate communication between data signals and command/address signals. However, there is no distinction between a channel transmitting command/address signals and a channel transmitting data signals. Therefore, to transmit command/address signals, a buffer chip must temporarily stop communication of data signals, which may slow down the operation speed of the storage device.

Some example embodiments of inventive concepts provide a storage device storage device including a memory controller configured to generate at least one of a chip enable signal and a one command/address signal, a buffer chip configured to receive the chip enable signal, the command/address signal, and a data signal from the memory controller, and a memory device including the at least one storage area, the at least one storage area configured to perform at least one of a write operation and a read operation, based on the command/address signal and the data signal received by the buffer chip. The buffer chip includes a first channel configured to receive the chip enable signal or the command/address signal, and a second channel configured to receive the data signal, wherein the first channel and the second channel may be configured to transmit signals received through separate paths to respective ones of the at least one storage.

Some example embodiments of inventive concepts provide a method of operating a storage device, the method including generating at least one of a chip enable signal and a command/address signal, receiving the chip enable signal, the command/address signal, and a data signal, and performing at least one of a write operation and a read operation, based on the received command/address signal and data signal. The receiving of the chip enable signal, the command/address signal, and the data signal includes receiving the chip enable signal or the command/address signal through a first channel, receiving the data signal through a second channel that is different from the first channel, and transmitting the received signals to respective ones of at least one storage area.

Some example embodiments of inventive concepts provide a buffer chip including a first channel configured to receive a chip enable signal or the command/address signal, and a second channel configured to receive a data signal, wherein the first channel and the second channel may be further configured to transmit signals received through separate paths to respective ones of at least one storage area.

### BRIEF DESCRIPTION OF THE DRAWINGS

Some example embodiments will be more clearly understood from the following detailed description taken in conjunction with the accompanying drawings in which:

FIG. 1 is a block diagram of a storage device according to an example embodiment;

FIG. 2 is a block diagram of a buffer chip according to an example embodiment;

FIGS. 3A to 3C are circuit diagrams of the storage device 100 according to an example embodiment;

FIG. 4 is a diagram illustrating signals received by a buffer chip according to an example embodiment;

FIG. 5A is a block diagram of a storage device including a plurality of chips according to an example embodiment;

FIG. 5B is a diagram illustrating signals that can be received by a buffer chip included in FIG. 5A;

FIG. 5C is a diagram in which a plurality of chips of a storage device are activated by a plurality of chip enable signals;

FIG. 5D is a diagram in which a plurality of chips of a storage device are activated by a plurality of chip enable signals;

FIGS. 6 and 7 are flowcharts of a method of operating a storage device according to an example embodiment;

FIG. 8 is a flowchart of a process for determining storage areas with which a first channel and a second channel communicate in a method of operating a storage device according to an example embodiment;

FIG. 9 is a flowchart of a process for controlling transmission of a command/address signal and a data signal in a method of operating a storage device according to an example embodiment;

FIGS. 10 to 12 are diagrams illustrating a three-dimensional V-NAND structure that can be applied to a memory device according to an example embodiment; and

FIG. 13 is a block diagram of a storage system according to an example embodiment.

### DETAILED DESCRIPTION

Hereinafter, various example embodiments are described with reference to the attached drawings. Details, such as detailed configuration and structure, are provided to help readers understand embodiments below. Therefore, example embodiments described herein may be changed or modified in various ways without departing from the present inventive concepts.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

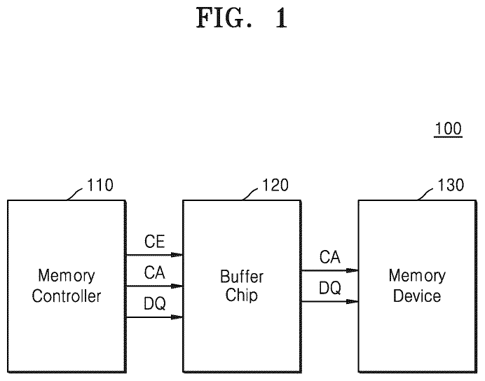

FIG. 1 is a block diagram of a storage device 100 according to an example embodiment.

Referring to FIG. 1, the storage device 100 according to an example embodiment may include a memory controller 110, a buffer chip 120, and a memory device 130. The storage device 100 according to an example embodiment may exchange signals simultaneously with at least one storage area. For example, the storage device 100 may transmit a chip enable signal CE, a command/address signal CA, or a data signal DQ generated from the memory controller 110 to the storage area of the memory device 130 through the buffer chip 120. In addition, the storage device 100 may transmit the data signal DQ, the chip enable signal CE, or the command/address signal CA, each read from the at least one storage area of the memory device 130, to the memory controller 110 through the buffer chip 120.

The memory controller 110 according to an example embodiment may generate a plurality of signals. For example, the memory controller 110 may generate at least one of the chip enable signal CE and the command/address signal CA for the at least one storage area of the memory device 130. The chip enable signal CE according to an example embodiment may be a signal that controls signal transmission of the buffer chip 120 to activate the command/address signal CA. The command/address signal CA according to an example embodiment may be a signal that designates a storage area of the memory device 130.

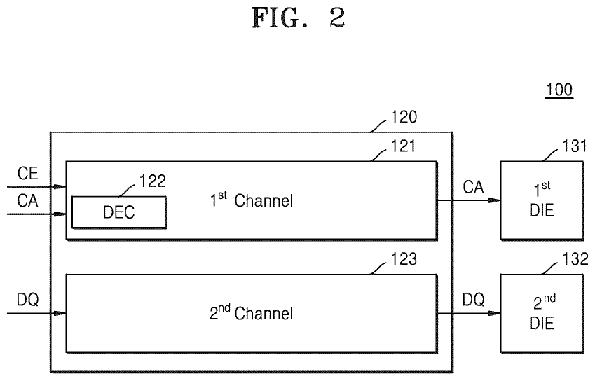

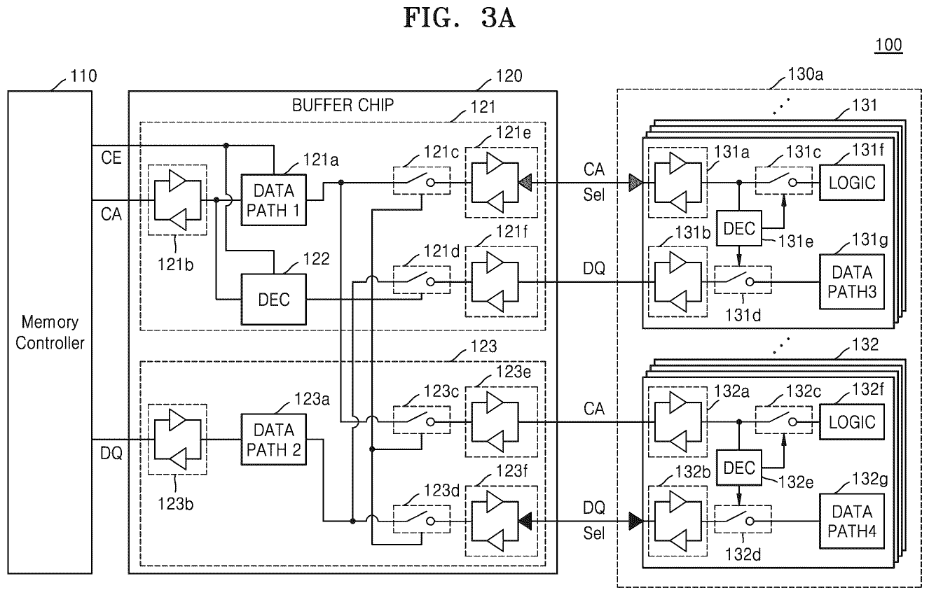

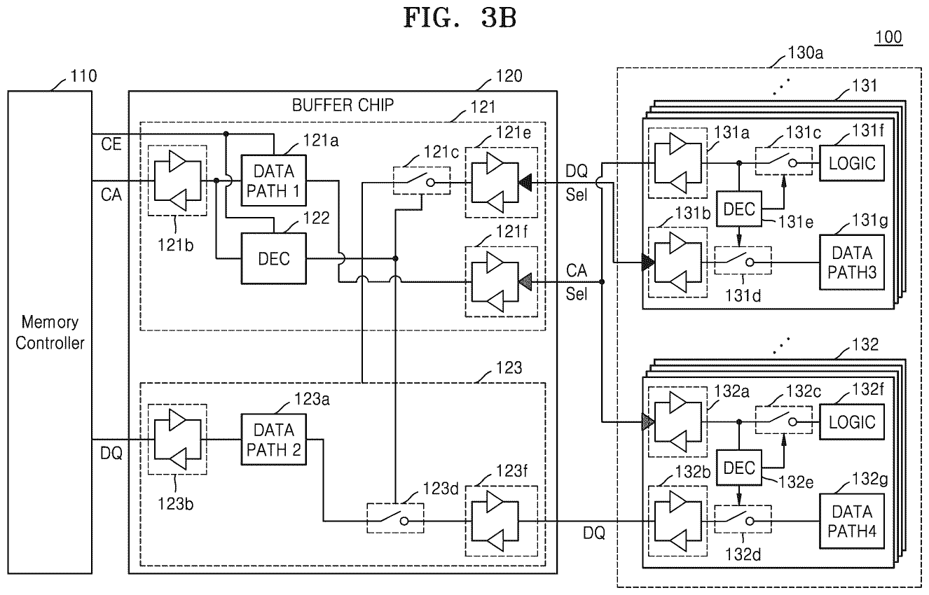

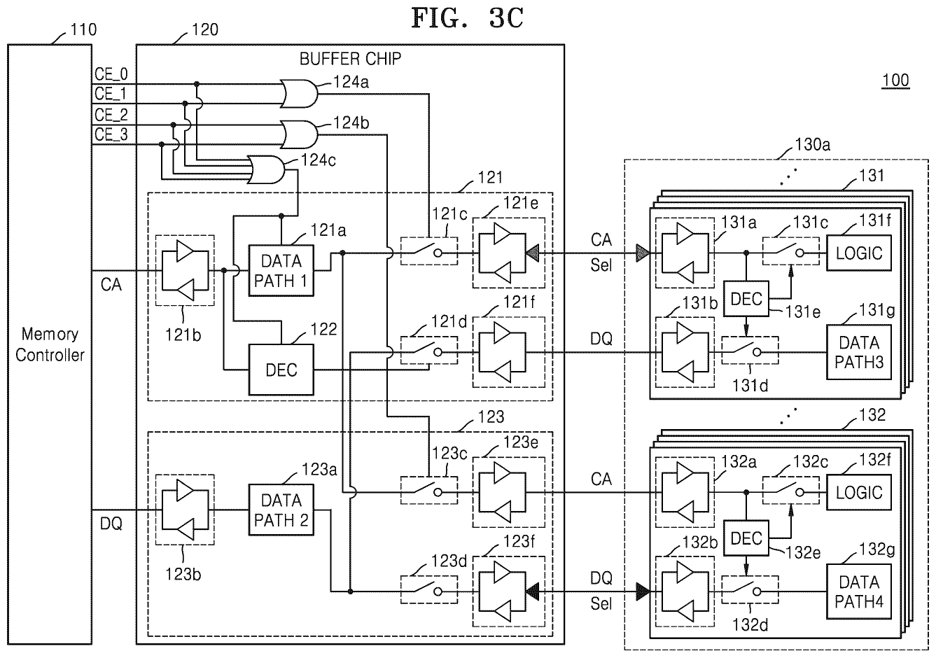

The memory controller 110 according to an example embodiment may transmit the data signal DQ to the buffer chip 120. For example, the memory controller 110 may transmit the command/address signal CA to the buffer chip 120, and the buffer chip 120 may transmit the data signal DQ to the designated storage area based on a result of decoding the command/address signal CA. The process of transmitting the data signal DQ is described in detail with reference to FIGS. 2, 3A, 3B, and 3C.

The buffer chip 120 according to an example embodiment may be configured to receive the chip enable signal CE, the command/address signal CA, and the data signal DQ from the memory controller 110. For example, the buffer chip 120 may be configured to include a first channel for receiving the chip enable signal CE or the command/address signal CA and a second channel for receiving the data signal DQ. The first channel according to an example embodiment may be a path for receiving the chip enable signal CE or the command/address signal CA. The second channel according to an example embodiment may be a path for receiving the data signal DQ. The first channel and the second channel according to an example embodiment may receive signals through separate paths and may transmit the received signals to the at least one storage area of the memory device 130. For example, the first channel and the second channel may be physically separate paths for signal transmission, wherein the first channel may receive the chip enable signal CE or the command/address signal CA while the second channel may receive the data signal DQ. The buffer chip 120 according to an example embodiment may simultaneously transmit signals received through the first channel and the second channel to the memory device 130.

The memory device 130 according to an example embodiment may include at least one storage area configured to perform at least one of a write operation and a read operation based on the command/address signal CA and the data signal DQ, each received by the buffer chip 120. The memory device 130 according to an example embodiment may include a first storage area and a second storage area. For example, the memory device 130 may include a first storage area that receives the command/address signal CA and a second storage area that receives the data signal DQ. The first storage area or the second storage area according to an example embodiment may each be a memory die included in the memory device 130. However, the first storage area and the second storage area are classified according to the type of signals received.

FIG. 2 is a block diagram of the buffer chip 120 according to an example embodiment.

Referring to FIGS. 1 and 2, the buffer chip 120 according to an example embodiment may include a first channel 121, a decoder 122, and a second channel 123.

The first channel 121 according to an example embodiment may receive the chip enable signal CE or the command/address signal CA and may transmit the received command/address signal CA to a first storage area 131. The first storage area 131 according to an example embodiment may be a storage area of the memory device 130 that communicates with the first channel 121. In FIG. 2, the first storage area 131 may be a memory die included in the memory device 130, but the unit of the first storage area 131 is not limited thereto.

The first channel 121 according to an example embodiment may be configured to transmit the command/address signal CA to a plurality of dies included in the memory device 130. For example, in FIG. 2, the first channel 121 communicates with one storage area, but the disclosed buffer chip 120 is not limited thereto. For example, the buffer chip 120 may communicate with a plurality of storage areas of the memory device 130 through a plurality of paths connected to the first channel 121.

The buffer chip 120 according to an example embodiment may include at least one decoder 122. For example, since the first channel 121 includes the decoder 122, the buffer chip 120 may include the decoder 122. The decoder 122 according to an example embodiment may decode the command/address signal CA. The buffer chip 120 according to an example embodiment may determine a storage area with which the first channel 121 communicates based on the result of decoding the command/address signal CA by the decoder 122. For example, when the first channel 121 is activated by the chip enable signal CE, the decoder 122 may decode the command/address signal CA and determine the first storage area 131 based on the decoding result. The command/address signal CA according to an example embodiment may include information about the storage area to which the command/address signal CA is to be transmitted.

The buffer chip 120 according to an example embodiment may be configured to determine a storage area with which the second channel 123 communicates based on the result of decoding the command/address signal CA. The second channel 123 according to an example embodiment may transmit the data signal DQ to the second storage area 132 based on the result of decoding the command/address signal CA. For example, based on the result of decoding the command/address signal CA by the decoder 122, the buffer chip 120 may determine the first storage area 131 and the second storage area 132 and may determine a storage area to which the command/address signal CA is not transmitted as the second storage area 132. The command/address signal CA according to an example embodiment may include path information of the data signal DQ.

The buffer chip 120 according to an example embodiment may be configured to communicate the data signal DQ with the second storage area 132 through the second channel 123 while the command/address signal CA is transmitted to the first storage area 131 through the first channel 121. For example, the first channel 121 and the second channel 123 may be physically separated and simultaneously transmit a plurality of signals to the memory device 130. While the command/address signal CA is transmitted to the first storage area 131 through the first channel 121, the buffer chip 120 according to an example embodiment may transmit the data signal DQ to the second storage area 132 through the second channel 123 so that a write operation or a read operation is performed. In addition, while the data signal DQ is transmitted to the first storage area 131 through the first channel 121, the buffer chip 120 according to an example embodiment may transmit the command/address signal CA to the second storage area 132 through the second channel 123 so that a write operation or a read operation is performed.

FIGS. 3A to 3C are circuit diagrams of the storage device 100 according to an example embodiment.

FIG. 3A shows the storage device 100 in which the independent paths of the command/address signal CA of the buffer chip 120 according to an example embodiment are connected to the first storage area 131 and the second storage area 132, respectively.

Referring to FIG. 3A, the buffer chip 120 according to an example embodiment may include a first channel 121 and a second channel 123, and the first channel 121 may include a first data path 121a, a first latch 121b, a first switch 121c, a second switch 121d, a second latch 121e, a third latch 121f, or a decoder 122.

The first data path 121a according to an example embodiment may be a path through which the chip enable signal CE and the command/address signal CA are transmitted.

The first latch 121b according to an example embodiment may receive the command/address signal CA. For example, the first latch 121b may receive the command/address signal CA and may transmit the received command/address signal CA to the decoder 122 when the received command/address signal CA is activated.

The decoder 122 according to an example embodiment may decode the command/address signal CA activated by the chip enable signal CE and may determine the path of the command/address signal CA and the path of the data signal DQ based on the decoding result. For example, the decoder 122 may decode the command/address signal CA and may determine the first storage area 131 to which the command/address signal CA is transmitted and the second storage area 132 to which the data signal DQ is transmitted, based on the decoding result. The buffer chip 120 may control the operation of first to fourth switches 121c, 121d, 123c, and 123d based on the decoding result, according to an example embodiment.

The first switch 121c according to an example embodiment may control transmission of the command/address signal CA. For example, when the first storage area 131 is determined as an area to which the command/address signal CA is transmitted based on the result of decoding the command/address signal CA by the decoder 122, the buffer chip 120 may transmit the command/address signal CA to the first storage area 131 by closing the first switch 121c. In some example embodiments, when the first switch 121c is closed, the path for transmitting the command/address signal CA to the first storage area 131 may be a selection path Sel.

The second switch 121d according to an example embodiment may control transmission of the data signal DQ. For example, when the first storage area 131 is determined as an area to which the data signal DQ is not transmitted based on the decoding result by the decoder 122, the buffer chip 120 may not transmit the data signal DQ to the first storage area 131 by opening the second switch 121d.

The second latch 121e according to an example embodiment may receive the command/address signal CA based on the result of decoding the command/address signal CA by the decoder 122 and may stably transmit the command/address signal CA to the first storage area 131. The third latch 121f according to an example embodiment may receive the data signal DQ based on the result of decoding the command/address signal CA by the decoder 122 and may stably transmit (or may transmit) the data signal DQ to the first storage area 131.

The second channel 123 according to an example embodiment may include a second data path 123a, a fourth latch 123b, the third switch 123c, the fourth switch 123d, a fifth latch 123e, or a sixth latch 123f.

The second data path 123a according to an example embodiment may be a path through which the data signal DQ is transmitted.

The fourth latch 123b according to an example embodiment may receive the data signal DQ. For example, when the area to which the data signal DQ is transmitted based on the decoding result by the first channel 121 is determined as the second storage area 132, the fourth latch 123b may transmit the received data signal DQ to the second storage area 132.

The third switch 123c according to an example embodiment may control transmission of the command/address signal CA. For example, in some example embodiments, when the second storage area 132 is determined as an area to which the command/address signal CA is not transmitted based on the decoding result by the decoder 122, the buffer chip 120 may not transmit the command/address signal CA to the second storage area 132 by opening the third switch 123c.

The fourth switch 123d according to an example embodiment may control transmission of the data signal DQ. For example, when the second storage area 132 is determined as an area to which the data signal DQ is transmitted based on the decoding result by the decoder 122 of the first channel 121, the buffer chip 120 may transmit the data signal DQ to the second storage area 132 by closing the fourth switch 123d. In some example embodiments, when the fourth switch 123d is closed, the path for transmitting the data signal DQ to the second storage area 132 may be a selection path Sel.

The fifth latch 123e according to an example embodiment may receive the command/address signal CA based on the result of decoding the command/address signal CA by the decoder 122 and may stably transmit (or may transmit) the command/address signal CA to the second storage area 132. The sixth latch 123f according to an example embodiment may receive the data signal DQ based on the result of decoding the command/address signal CA by the decoder 122 and may stably transmit (or may transmit) the data signal DQ to the second storage area 132.

The first storage area 131 according to an example embodiment may include a seventh latch 131a, an eighth latch 131b, a fifth switch 131c, a sixth switch 131d, a first storage area decoder 131e, a first storage area logic 131f, or a third data path 131g.

The seventh latch 131a according to an example embodiment may receive the command/address signal CA from the first channel 121 and may transmit the received command/address signal CA to the first storage area decoder 131e. The eighth latch 131b according to an example embodiment may receive the data signal DQ from the first channel 121.

According to an example embodiment, the operation of the fifth switch 131c and the sixth switch 131d may be controlled according to the decoding result by the first storage area decoder 131e. For example, when the operation determined based on the result of decoding the command/address signal CA by the first storage area decoder 131e is a read operation, the fifth switch 131c may be closed and the command/address signal CA may be transmitted to the first storage area logic 131f. In some example embodiments, when the operation determined based on the result of decoding the command/address signal CA by the first storage area decoder 131e is a write operation, the sixth switch 131d may be closed and the data signal DQ may be connected to the third data path 131g. The third data path 131g according to an example embodiment may be a path for writing data to the first storage area 131.

The second storage area 132 according to an example embodiment may include a ninth latch 132a, a tenth latch 132b, a seventh switch 132c, an eighth switch 132d, a second storage area decoder 132e, a second storage area logic 132f, or a fourth data path 132g.

The ninth latch 132a according to an example embodiment may receive the command/address signal CA from the second channel 123 and may transmit the received command/address signal CA to the second storage area decoder 132e. The tenth latch 132b according to an example embodiment may receive the data signal DQ from the second channel 123.

According to an example embodiment, the operation of the seventh switch 132c and the eighth switch 132d may be controlled according to the decoding result by the second storage area decoder 132e, or the opening and closing of the seventh switch 132c and the eighth switch 132d may be controlled based on the result of decoding the command/address signal CA by the decoder 122 of the buffer chip 120. For example, when the operation determined based on the result of decoding the command/address signal CA by the second storage area decoder 132e is a read operation, the seventh switch 132c may be closed and the command/address signal CA may be transmitted to the second storage area logic 132f. In some example embodiments, when the operation determined based on the result of decoding the command/address signal CA by the second storage area decoder 132e is a write operation, or when the data signal DQ is received based on the result of decoding the command/address signal CA by the decoder 122 of the buffer chip 120, the eighth switch 132d may be closed and the data signal DQ may be transmitted to the fourth data path 132g. The fourth data path 132g according to an example embodiment may be a path for writing data to the second storage area 132.

Although only the first storage area 131 and the second storage area 132 are shown in FIG. 3A, the number of storage areas is not limited thereto, and there may be more storage areas including a plurality of dies.

FIG. 3B shows the storage device 100 in which the command/address signal CA of the buffer chip 120 according to an example embodiment is transmitted to the first storage area 131 and the second storage area 132 through one path.

Since the configuration of the memory controller 110, the first storage area 131, and the second storage area 132 in FIG. 3B is the same as in FIG. 3A, FIG. 3B is described focusing on the differences from FIG. 3A.

Referring to FIG. 3B, the buffer chip 120 according to an example embodiment may include a first channel 121 and a second channel 123, and the first channel 121 may include a first data path 121a, a first latch 121b, a first switch 121c, a second latch 121e, a third latch 121f, or a decoder 122. The second channel 123 according to an example embodiment may include a second data path 123a, a fourth latch 123b, a fourth switch 123d, or a sixth latch 123f. For example, unlike FIG. 3A, the command/address signal CA may be connected to a plurality of storage areas and a plurality of paths through the third latch 121f, and the path of the command/address signal CA or the data signal DQ may be determined based on the result of decoding the command/address signal CA by decoders in the storage areas.

The first data path 121a according to an example embodiment may be a path through which the chip enable signal CE and the command/address signal CA are transmitted.

The first latch 121b according to an example embodiment may receive the command/address signal CA. For example, the first latch 121b may receive the command/address signal CA and may transmit the received command/address signal CA to the decoder 122 when the received command/address signal CA is activated.

The decoder 122 according to an example embodiment may decode the command/address signal CA activated by the chip enable signal CE and may determine the path of the command/address signal CA and the path of the data signal DQ based on the decoding result. For example, the decoder 122 may decode the command/address signal CA and may determine the first storage area 131 to which the command/address signal CA is transmitted and the second storage area 132 to which the data signal DQ is transmitted, based on the decoding result. The buffer chip 120 of FIG. 3B according to an example embodiment may control the operation of the first switch 121c or the fourth switch 123d according to the decoding result.

The decoder 122 of the first channel 121 according to an example embodiment may decode the command/address signal CA, and based on the decoding result, the buffer chip 120 may determine a storage area to which the data signal DQ is transmitted. For example, the buffer chip 120 may decode the command/address signal CA and may determine the storage area to which the data signal DQ is transmitted as the second storage area 132 based on the decoding result. In some example embodiments, when the storage area to which the data signal DQ is transmitted is determined as the second storage area 132, the buffer chip 120 may transmit the data signal DQ to the second storage area 132 by closing the fourth switch 123d. In another example, the buffer chip 120 may decode the command/address signal CA and may determine the storage area to which the data signal DQ is transmitted as the first storage area 131 based on the decoding result. In some example embodiments, when the storage area to which the data signal DQ is transmitted is determined as the first storage area 131, the buffer chip 120 may transmit the data signal DQ to the first storage area 131 by closing the first switch 123a. According to an example embodiment, the path through which the data signal DQ is transmitted from the buffer chip 120 to the storage area may be a selection path Sel.

The buffer chip 120 according to an example embodiment may transmit a command/address signal CA to a plurality of storage areas through respective paths. For example, the buffer chip 120 does not have a separate switch to control transmission of the command/address signal CA but may transmit the command/address signal CA to the plurality of storage areas through the third latch 121f.

In some example embodiments, when the command/address signal CA is transmitted to the plurality of storage areas, each storage area may decode the command/address signal CA through a decoder included in the storage area. For example, the first storage area 131 may decode the received command/address signal CA through the first storage area decoder 131e and may perform an operation according to the decoding result. For example, the first storage area 131 may perform a read operation or a write operation on the data signal DQ according to the result of decoding the command/address signal CA. In another example, the second storage area 132 may decode the received command/address signal CA through the second storage area decoder 132e and may perform an operation according to the decoding result. For example, the second storage area 132 may perform a read operation or a write operation on the data signal DQ according to the result of decoding the command/address signal CA. The path through which the command/address signal CA is transmitted from the buffer chip 120 to the storage area according to an example embodiment may be the selection path Sel.

Although only the first storage area 131 and the second storage area 132 are shown in FIG. 3B, the number of storage areas is not limited thereto, and there may be more storage areas including a plurality of dies.

FIG. 3C shows an example embodiment in which a plurality of chip enable signals CE_0, CE_1, CE_2, and CE_3 are received by the buffer chip 120 according to an example embodiment.

Since the configuration of the memory controller 110, the first storage area 131, and the second storage area 132 in FIG. 3C is the same as in FIG. 3A, FIG. 3C is described focusing on the differences from FIG. 3A.

Referring to FIG. 3C, the buffer chip 120 according to an example embodiment may include a first channel 121 and a second channel 123, and the first channel 121 may include a first data path 121a, a first latch 121b, a first switch 121c, a second switch 121d, a second latch 121e, a third latch 121f, or a decoder 122. The first data path 121a according to an example embodiment may be a path through which the chip enable signal CE and the command/address signal CA are transmitted.

The second channel 123 according to an example embodiment may include a second data path 123a, a fourth latch 123b, a third switch 123c, a fourth switch 123d, a fifth latch 123e, or a sixth latch 123f. The second data path 123a according to an example embodiment may be a path through which the data signal DQ is transmitted.

The buffer chip 120 according to an example embodiment may receive the plurality of chip enable signals CE_0, CE_1, CE_2, and CE_3. The buffer chip 120 according to an example embodiment may receive the plurality of chip enable signals CE_0, CE_1, CE_2, and CE_3 and may determine the path of the command/address signal CA and the path of the data signal DQ. For example, the buffer chip 120 may distinguish the types of the plurality of chip enable signals CE_0, CE_1, CE_2, and CE_3 and may activate the received plurality of chip enable signals CE_0, CE_1, CE_2, and CE_3 to activate the first switch 121c of the first channel 121 or the third switch 123c of the second channel 123. The first switch 121c of the first channel 121 or the third switch 123c of the second channel 123 according to an example embodiment may be a switch that controls connection of the paths of the command/address signal CA.

The buffer chip 120 according to an example embodiment may distinguish the plurality of chip enable signals CE_0, CE_1, CE_2, and CE_3 by using a first logic circuit 124a or a second logic circuit 124b. For example, each of the first logic circuit 124a and the second logic circuit 124b may be composed of an OR gate and may activate the first switch 121c and the third switch 123c depending on the states of the first chip enable signal CE_0 and the second chip enable signal CE_1. The buffer chip 120 according to an example embodiment may open the first switch 121c when the output of the first logic circuit 124a has a high logic value and may close the first switch 121c when the output of the first logic circuit 124a has a low logic value. The buffer chip 120 according to an example embodiment may open the third switch 123c when the output of the second logic circuit 124b has a high logic value and may close the third switch 123c when the output of the second logic circuit 124b has a low logic value.

The first logic circuit 124a or the second logic circuit 124b according to an example embodiment may be an OR gate, but example embodiments are not limited thereto.

For example, the buffer chip 120 according to an example embodiment may distinguish the types of the plurality of chip enable signals CE_0, CE_1, CE_2, and CE_3, may activate the received plurality of chip enable signals CE_0, CE_1, CE_2, and CE_3 to decode the command/address signal CA, and may activate the second switch 121d of the first channel 121 or the third switch 123c of the second channel 123. The second switch 121d of the first channel 121 or the third switch 123c of the second channel 123 according to an example embodiment may be a switch for controlling the connection of the paths of the data signal DQ.

The plurality of chip enable signals CE_0, CE_1, CE_2, and CE_3 according to an example embodiment may be distinguished by a third logic circuit 124c. For example, the buffer chip 120 may determine a storage area to which the command/address signal CA is transmitted based on the output of the third logic circuit 124c. In some example embodiments, when the output of the third logic circuit 124c is high, the decoder 122 may decode the command/address signal CA and may determine the storage area to which the command/address signal CA is transmitted. However, when the output of the third logic circuit 124c is low, the decoder 122 may not be activated. The third logic circuit 123a according to an example embodiment may be an OR gate, but example embodiments are not limited thereto.

The first latch 121b according to an example embodiment may receive the command/address signal CA. For example, the first latch 121b may receive the command/address signal CA and may transmit the received command/address signal CA to the decoder 122 when the received command/address signal CA is activated.

The decoder 122 according to an example embodiment may decode the command/address signal CA activated by the chip enable signal CE and may determine the path of the command/address signal CA and the path of the data signal DQ based on the decoding result. For example, the decoder 122 may decode the command/address signal CA and may determine the first storage area 131 to which the command/address signal CA is transmitted and the second storage area 132 to which the data signal DQ is transmitted, based on the decoding result. The buffer chip 120 may control the operation of the first to fourth switches 121c, 121d, 123c, and 123d based on the decoding result, according to an example embodiment.

The first switch 121c according to an example embodiment may control transmission of the command/address signal CA. For example, when the first storage area 131 is determined as an area to which the command/address signal CA is transmitted based on the result of decoding the command/address signal CA by the decoder 122, the buffer chip 120 may transmit the command/address signal CA to the first storage area 131 by closing the first switch 121c. In some example embodiments, when the first switch 121c is closed, the path for transmitting the command/address signal CA to the first storage area 131 may be a selection path Sel.

The second switch 121d according to an example embodiment may control transmission of the data signal DQ. For example, when the first storage area 131 is determined as an area to which the data signal DQ is not transmitted based on the decoding result by the decoder 122, the buffer chip 120 may not transmit the data signal DQ to the first storage area 131 by opening the second switch 121d.

The second latch 121e according to an example embodiment may receive the command/address signal CA based on the result of decoding the command/address signal CA by the decoder 122 and may stably transmit (or may transmit) the command/address signal CA to the first storage area 131. The third latch 121f according to an example embodiment may receive the data signal DQ based on the result of decoding the command/address signal CA by the decoder 122 and may stably transmit (or may transmit) the data signal DQ to the first storage area 131.

The fourth latch 123b according to an example embodiment may receive the data signal DQ. For example, when the area to which the data signal DQ is transmitted based on the decoding result by the first channel 121 is determined as the second storage area 132, the fourth latch 123b may transmit the received data signal DQ to the second storage area 132.

The third switch 123c according to an example embodiment may control transmission of the command/address signal CA. For example, when the second storage area 132 is determined as an area to which the command/address signal CA is not transmitted based on the decoding result by the decoder 122, the buffer chip 120 may not transmit the command/address signal CA to the second storage area 132 by opening the third switch 123c.

The fourth switch 123d according to an example embodiment may control transmission of the data signal DQ. For example, when the second storage area 132 is determined as an area to which the data signal DQ is transmitted based on the decoding result by the decoder 122 of the first channel 121, the buffer chip 120 may transmit the data signal DQ to the second storage area 132 by closing the fourth switch 123d. In some example embodiments, when the fourth switch 123d is closed, the path for transmitting the data signal DQ to the second storage area 132 may be a selection path Sel.

The fifth latch 123e according to an example embodiment may receive the command/address signal CA based on the result of decoding the command/address signal CA by the decoder 122 and may stably transmit (or may transmit) the command/address signal CA to the second storage area 132. The sixth latch 123f according to an example embodiment may receive the data signal DQ based on the result of decoding the command/address signal CA by the decoder 122 and may stably transmit (or may transmit) the data signal DQ to the second storage area 132.

The first storage area 131 according to an example embodiment may include a seventh latch 131a, an eighth latch 131b, a fifth switch 131c, a sixth switch 131d, a first storage area decoder 131e, a first storage area logic 131f, or a third data path 131g.

The seventh latch 131a according to an example embodiment may receive the command/address signal CA from the first channel 121 and may transmit the received command/address signal CA to the first storage area decoder 131e. The eighth latch 131b according to an example embodiment may receive the data signal DQ from the first channel 121.

According to an example embodiment, the operation of the fifth switch 131c and the sixth switch 131d may be controlled according to the decoding result by the first storage area decoder 131e. For example, when the operation determined based on the result of decoding the command/address signal CA by the first storage area decoder 131e is a read operation, the fifth switch 131c may be closed and the command/address signal CA may be transmitted to the first storage area logic 131f. In some example embodiments, when the operation determined based on the result of decoding the command/address signal CA by the first storage area decoder 131e is a write operation, the sixth switch 131d may be closed and the data signal DQ may be transmitted to the third data path 131g. The third data path 131g according to an example embodiment may be a path for writing data to the first storage area 131.

The second storage area 132 according to an example embodiment may include a ninth latch 132a, a tenth latch 132b, a seventh switch 132c, an eighth switch 132d, a second storage area decoder 132e, a second storage area logic 132f, or a fourth data path 132g.

The ninth latch 132a according to an example embodiment may receive the command/address signal CA from the second channel 123 and may transmit the received command/address signal CA to the second storage area decoder 132e. The tenth latch 132b according to an example embodiment may receive the data signal DQ from the second channel 123.

According to an example embodiment, the operation of the seventh switch 132c and the eighth switch 132d may be controlled according to the decoding result by the second storage area decoder 132e, or the opening and closing of the seventh switch 132c and the eighth switch 132d may be controlled based on the result of decoding the command/address signal CA by the decoder 122 of the buffer chip 120. For example, when the operation determined based on the result of decoding the command/address signal CA by the second storage area decoder 132e is a read operation, the seventh switch 132c may be closed and the command/address signal CA may be transmitted to the second storage area logic 132f. In some example embodiments, when the operation determined based on the result of decoding the command/address signal CA by the second storage area decoder 132e is a write operation, or when the data signal DQ is received based on the result of decoding the command/address signal CA by the decoder 122 of the buffer chip 120, the eighth switch 132d may be closed and the data signal DQ may be transmitted to the fourth data path 132g. The fourth data path 132g according to an example embodiment may be a path for writing data to the second storage area 132.

Although only the first storage area 131 and the second storage area 132 are shown in FIG. 3C, the number of storage areas is not limited thereto, and there may be more storage areas including a plurality of dies.

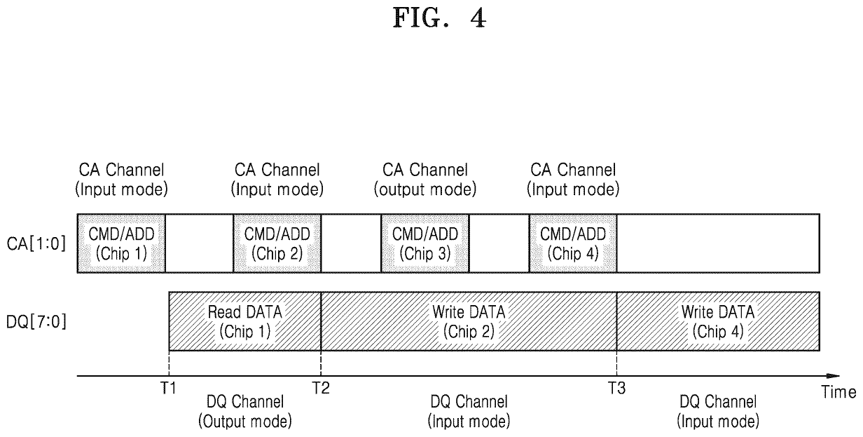

FIG. 4 is a diagram illustrating signals received by the buffer chip 120 according to an example embodiment.

Referring to FIGS. 2 and 4, the buffer chip 120 according to an example embodiment may receive the command/address signal CA through a CA channel and may receive the data signal DQ through a DQ channel. The CA channel according to an example embodiment may be the first channel 121 of FIG. 2, and the DQ channel may be the second channel 123 of FIG. 2. In FIG. 4, a memory device according to an example embodiment may be composed of a plurality of chips. For example, although the memory device may be described as including first to fourth chips, the memory device may further include a plurality of chips.

The buffer chip 120 according to an example embodiment may receive the command/address signal CA for the first chip in input mode through the first channel 121 until a first time point T1. The input mode according to an example embodiment may be a mode in which the command/address signal CA is input to the storage area.

For example, the buffer chip 120 may receive the command/address signal CA including read data on the first chip through the first channel 121 until the first time point T1. In some example embodiments, when receiving the command/address signal CA including the read data on the first chip, the buffer chip 120 may cause the first chip to receive the data signal DQ in output mode from the first time point T1 to the second time point T2 and to perform a read operation. The output mode according to an example embodiment may be a mode for reading data from a storage area. While the first chip receives the data signal DQ, the first channel 121 may transmit the command/address signal CA to the second chip. For example, the buffer chip 120 according to an example embodiment may simultaneously transmit the command/address signal CA and the data signal DQ to separate storage areas.

The buffer chip 120 according to an example embodiment may receive the command/address signal CA for the second chip in input mode through the first channel 121 until the second time point T2. For example, the buffer chip 120 may receive the command/address signal CA including write data on the second chip through the first channel 121 until the second time point T2. In some example embodiments, when receiving the command/address signal CA including the write data on the second chip, the buffer chip 120 may cause the second chip to receive the data signal DQ in input mode from the second time point T2 to the third time point T3 and to perform a write operation. While the second chip receives the data signal DQ, the first channel 121 may transmit the command/address signal CA to the third chip in output mode and may transmit the command/address signal CA to the fourth chip in input mode. For example, the buffer chip 120 according to an example embodiment may simultaneously transmit the command/address signal CA and the data signal DQ to separate storage areas in input mode and output mode.

In some example embodiments, when receiving the command/address signal CA for the fourth chip in input mode, the buffer chip 120 may perform a write operation on the fourth chip after the third time point T3.

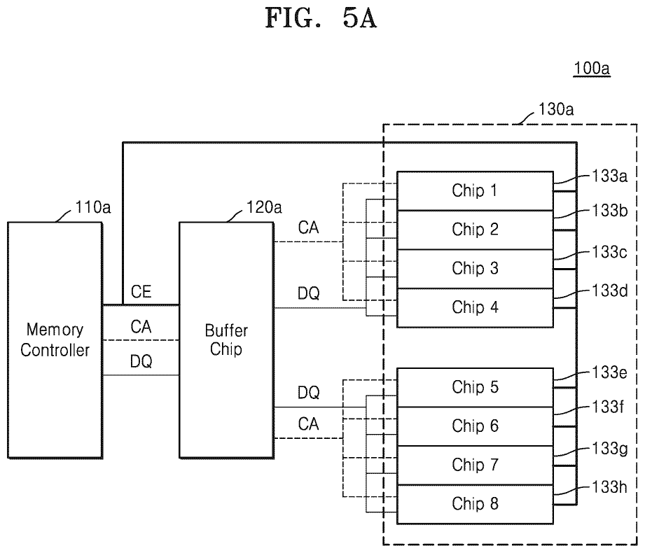

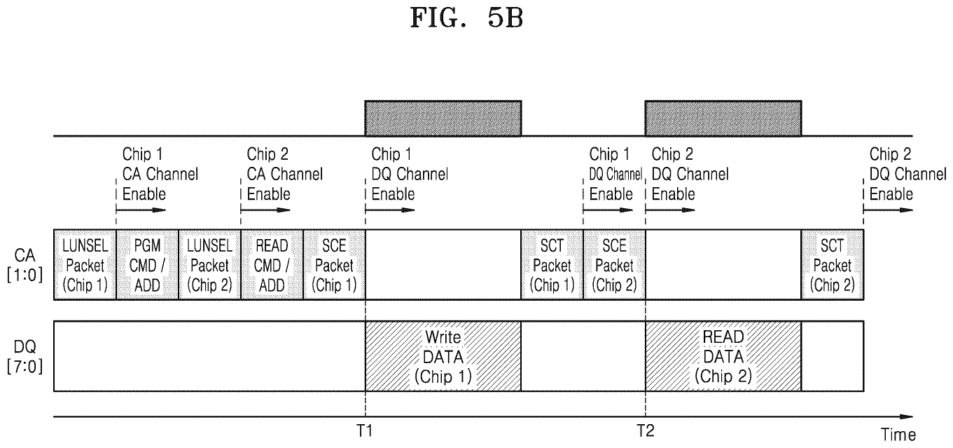

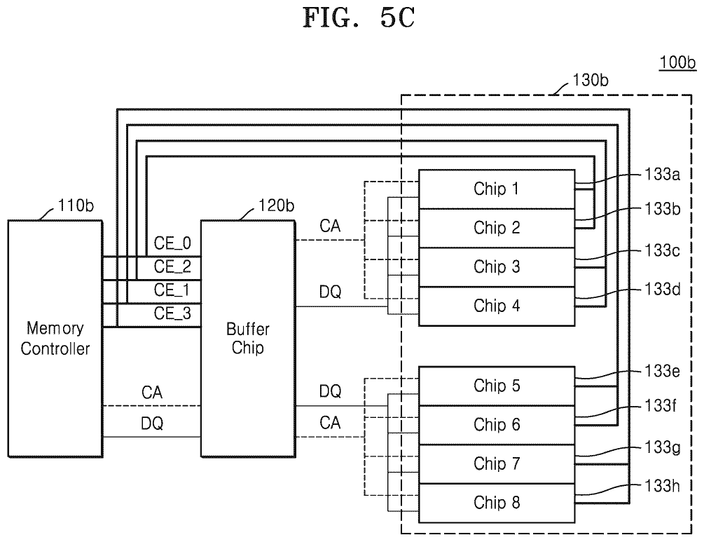

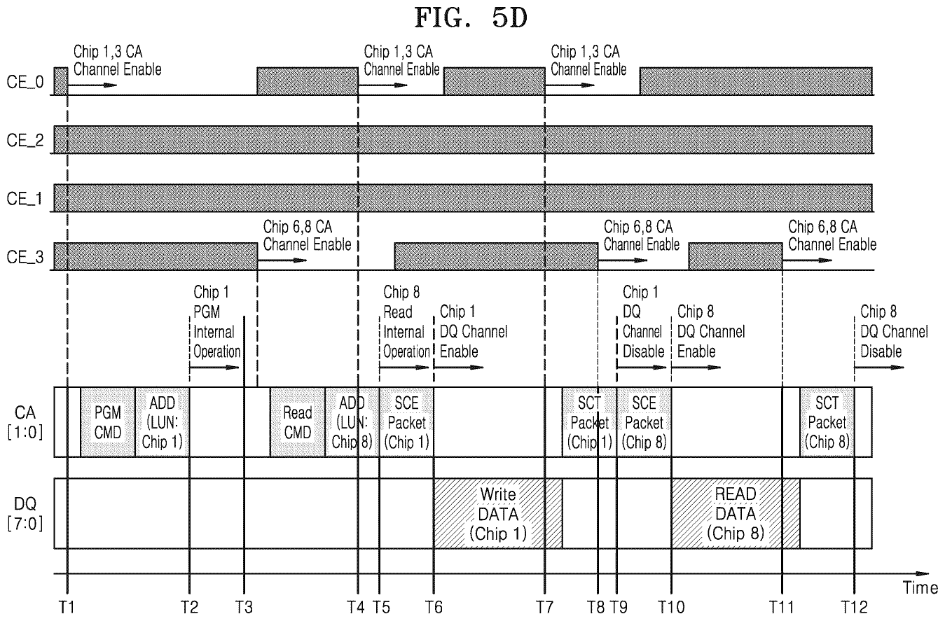

FIG. 5A is a block diagram of a storage device including a plurality of chips according to an example embodiment. FIG. 5B is a diagram illustrating signals that can be received by a buffer chip included in FIG. 5A.

Referring to FIG. 5A, a storage device 100a according to an example embodiment may include a memory controller 110a, a buffer chip 120a, and a memory device 130a. Since the configuration of the memory controller 110a and the buffer chip 120a of the storage device 100a in FIG. 5A is the same as that of FIGS. 1 and 2, the memory device 130a in FIG. 5A is described focusing on the differences from that of FIGS. 1 and 2.

The memory device 130a according to an example embodiment may include a plurality of chips. For example, the memory device 130a may include first to eighth chips 133a, 133b, 133c, 133d, 133e, 133f, 133g, and 133h. However, the number of memory chips is not limited thereto, and the memory device 130a may further include a plurality of memory chips.

According to an example embodiment, the first to eighth chips 133a, 133b, 133c, 133d, 133e, 133f, 133g, and 133h may each be connected to the chip enable signal CE and may each be connected to a command/address signal CA channel and a data signal DQ channel through the buffer chip 120a.

Referring to FIGS. 5A and 5B, the first chip 133a according to an example embodiment may receive the chip enable signal CE (LUNSEL Packet) and may receive a write command/address signal CA (PGM CMD/ADD) activated by the chip enable signal CE (LUNSEL Packet) for the first chip 133a. Likewise, the second chip 133b according to an example embodiment may receive the chip enable signal CE (LUNSEL Packet) and may receive a read command/address signal CA (READ CMD/ADD) activated by the chip enable signal CE (LUNSEL Packet) for the second chip 133b. In some example embodiments, when reception of a signal is completed, an operation execution signal (SCE Packet) for a chip may be received. For example, the buffer chip 120a may receive the operation execution signal (SCE Packet) for the first chip 133a and may cause the first chip 133a to perform an operation indicated by the write command/address signal CA (PGM CMD/ADD). The first chip 133a according to an example embodiment may receive the write data at the first time point T1 and may perform a data write operation indicated by the write command/address signal CA (PGM CMD/ADD).

In some example embodiments, when reception of the write data of the first chip 133a is completed, the buffer chip 120a may receive the operation completion signal (SCT Packet) and may receive the operation execution signal (SCE Packet) for the next chip. For example, when reception of the write data of the first chip 133a is completed, the buffer chip 120a may receive the operation completion signal (SCT Packet) for the first chip 133a and may receive the operation execution signal (SCE Packet) for the second chip 133b. In some example embodiments, when the operation execution signal (SCE Packet) for the second chip 133b is received, the second chip 133b may receive the read data based on the previously received read command/address signal CA (READ CMD/ADD). In some example embodiments, when reception of the read data is completed, the buffer chip 120a may receive the operation completion signal (SCT Packet).

For example, a plurality of chips of the storage device 100a according to an example embodiment may each simultaneously receive the chip enable signal CE and the command/address signal CA and may independently perform a data read operation or a data write operation according to an operation indicated by the command/address signal CA.

FIG. 5C is a diagram in which a plurality of chips of a storage device are activated by a plurality of chip enable signals CE_0, CE_1, CE_2, and CE_3.

Referring to FIG. 5C, a storage device 100b according to an example embodiment may include a memory controller 110b, a buffer chip 120b, and a memory device 130b. Since the configuration of the memory controller 110b and the buffer chip 120b of the storage device 100b in FIG. 5C is the same as that of FIGS. 1 and 2, the memory device 130b of FIG. 5C is described focusing on the differences from that of FIGS. 1 and 2.

The memory device 130b according to an example embodiment may include a plurality of chips. For example, the memory device 130b may include first to eighth chips 133a, 133b, 133c, 133d, 133e, 133f, 133g, and 133h. However, the number of memory chips is not limited thereto, and the memory device 130b may further include a plurality of memory chips.

According to an example embodiment, the first to eighth chips 133a, 133b, 133c, 133d, 133e, 133f, 133g, and 133h may each be connected to the chip enable signal CE and may each be connected to the command/address signal CA channel and data signal DQ channel through the buffer chip 120b. For example, the first to eighth chips 133a, 133b, 133c, 133d, 133e, 133f, 133g, and 133h may each be connected to a pre-classified chip enable signal CE channel, and may each receive the command/address signal CA or the data signal DQ from the buffer chip 120b when the chip enable signal CE is received.

The first chip enable signal CE_0 according to an example embodiment may be a signal that activates the first chip 133a or the second chip 133b. The second chip enable signal CE_1 according to an example embodiment may be a signal that activates the fifth chip 133e or the sixth chip 133f. The third chip enable signal CE_2 according to an example embodiment may be a signal that activates the third chip 133c or the fourth chip 133d. The fourth chip enable signal CE_3 according to an example embodiment may be a signal that activates the seventh chip 133g or the eight chip 133h.

FIG. 5D shows signals when a plurality of chips of a storage device according to an example embodiment are activated by the plurality of chip enable signals CE_0, CE_1, CE_2, and CE_3.

Referring to FIGS. 5C and 5D, according to an example embodiment, the first chip 133a and the third chip 133c may receive the first chip enable signal CE_0 at a first time point T1, a fourth time point T4, and a seventh time point T7, and may perform an internal programming operation at a second time point T2.

In addition, according to an example embodiment, the sixth chip 133f and the eighth chip 133h may receive the fourth chip enable signal CE_3 at a third time point T3, an eight time point T8, or an eleventh time point T11, and may receive the command/address signal CA including a read command signal (READ CMD) until a fifth time point T5. For example, the buffer chip 120b may receive the operation execution signal (SCE Packet) for the first chip 133a at a sixth time point T6, and may cause the first chip 133a to perform an operation indicated by the write command/address signal CA (PGM CMD/ADD). The first chip 133a according to an example embodiment may receive write data at the first time point T1 and may perform a data write operation indicated by the write command/address signal CA (PGM CMD/ADD).

In some example embodiments, when reception of the write data of the first chip 133a is completed, the buffer chip 120b may receive the operation completion signal (SCT Packet) and may receive the operation execution signal (SCE Packet) for the next chip. According to an example embodiment, the eighth chip 133h may receive the fourth chip enable signal CE_3, and may receive the read command/address signal CA (READ CMD) for the eighth chip 133h. In some example embodiments, when reception of the signal is completed, the operation execution signal (SCE Packet) for the eighth chip 133h may be received at a ninth time point T9. For example, when reception of the write data of the first chip 133a is completed, the buffer chip 120b may receive the operation completion signal (SCT Packet) for the first chip 133a and may receive the operation execution signal (SCE Packet) for the eighth chip 133h at the ninth time point T9. In some example embodiments, when the operation execution signal (SCE Packet) for the eight chip 133h is received, the eighth chip 133h may receive the read data until a twelfth time point T12 based on the previously received read command/address signal CA (READ CMD/ADD). In some example embodiments, when reception of the read data is completed, the buffer chip 120b may receive the operation completion signal (SCT Packet).

For example, a plurality of chips of the storage device 100b according to an example embodiment may each receive the chip enable signal CE and the command/address signal CA and may independently perform a data read operation or a data write operation according to an operation indicated by the command/address signal CA.

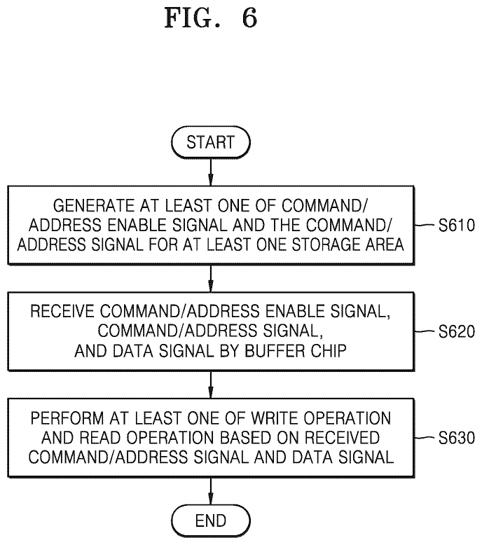

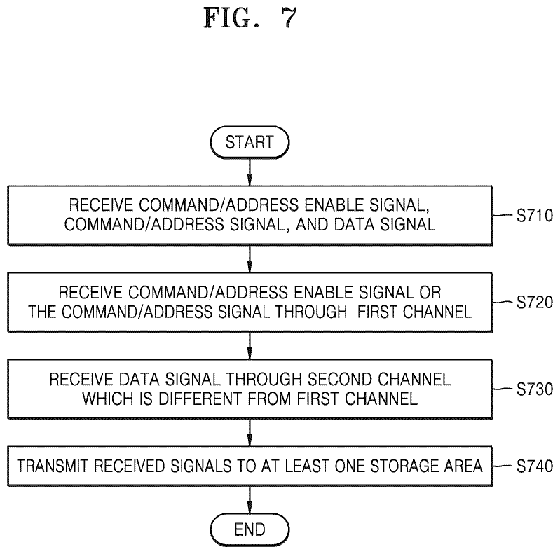

FIGS. 6 and 7 are flowcharts of a method of operating a storage device according to an example embodiment.

Referring to FIGS. 1 and 6, according to an example embodiment, the storage device 100 may generate at least one of the chip enable signal CE and the command/address signal CA for at least one storage area (S610).

For example, the storage device 100 may generate at least one of the chip enable signal CE and the command/address signal CA for the at least one storage area of the memory device 130. The chip enable signal CE according to an example embodiment may be a signal that controls signal transmission of the buffer chip 120 to activate the command/address signal CA. The command/address signal CA according to an example embodiment may be a signal that designates a storage area of the memory device 130.

In some example embodiments, when at least one of the chip enable signal CE and the command/address signal CA for at least one storage area is generated, the buffer chip 120 of the storage device 100 may receive the chip enable signal CE, the command/address signal CA, and the data signal DQ (S620).

For example, the buffer chip 120 of the storage device 100 may be configured to include a first channel for receiving the chip enable signal CE or the command/address signal CA and a second channel for receiving the data signal DQ. The first channel according to an example embodiment may be a path for receiving the chip enable signal CE or the command/address signal CA. The second channel according to an example embodiment may be a path for receiving the data signal DQ. The first channel and the second channel according to an example embodiment may receive signals through separate paths and may transmit the received signals to the at least one storage area of the memory device 130. For example, the first channel and the second channel may be physically separate paths for signal transmission, and the first channel may receive the chip enable signal CE or the command/address signal CA while the second channel may receive the data signal DQ. The buffer chip 120 according to an example embodiment may simultaneously transmit signals received through the first channel and the second channel to the memory device 130.

In some example embodiments, when the buffer chip 120 receives the chip enable signal CE, the command/address signal CA, and the data signal DQ, the storage device 100 may perform at least one of a write operation and a read operation, based on the received command/address signal CA and data signal DQ (S630).

The storage device 100 according to an example embodiment may include at least one storage area configured to perform at least one of a write operation and a read operation based on the command/address signal CA and the data signal DQ, each received by the buffer chip 120. The memory device 130 of the storage device 100 according to an example embodiment may include a first storage area and a second storage area. For example, the memory device 130 may include the first storage area that receives the command/address signal CA and the second storage area that receives the data signal DQ. The first storage area or the second storage area according to an example embodiment may each be a memory die included in the memory device 130. However, the first storage area and the second storage area are classified according to the type of signals received.

Referring to FIGS. 1, 2, and 7, the buffer chip 120 of the storage device 100 according to an example embodiment may receive the chip enable signal CE, the command/address signal CA, and the data signal DQ (S710).

In some example embodiments, when the chip enable signal CE, the command/address signal CA, and the data signal DQ are received, the storage device 100 may receive the chip enable signal CE or the command/address signal CA through the first channel 121 (S720).

The buffer chip 120 according to an example embodiment may receive the chip enable signal CE or the command/address signal CA and may transmit the received command/address signal CA to the first storage area 131. The first storage area 131 according to an example embodiment may be a storage area of the memory device 130 that communicates with the first channel 121.

In some example embodiments, when the chip enable signal CE or the command/address signal CA is received through the first channel 121, the data signal DQ may be received through the second channel 123, which is different from the first channel 121 (S730). The buffer chip 120 according to an example embodiment may be configured to communicate the data signal DQ with the second storage area 132 through the second channel 123 while the command/address signal CA is transmitted to the first storage area 131 through the first channel 121.

In some example embodiments, when the command/address signal CA is received through the first channel 121 and the data signal DQ is received through the second channel 123, the storage device 100 may transmit the received signals to at least one storage area (S740).

For example, the first channel 121 and the second channel 123 may be physically separated and simultaneously transmit a plurality of signals to the memory device 130. While the command/address signal CA is transmitted to the first storage area 131 through the first channel 121, the buffer chip 120 according to an example embodiment may transmit the data signal DQ to the second storage area 132 through the second channel 123 so that a write operation or a read operation is performed.

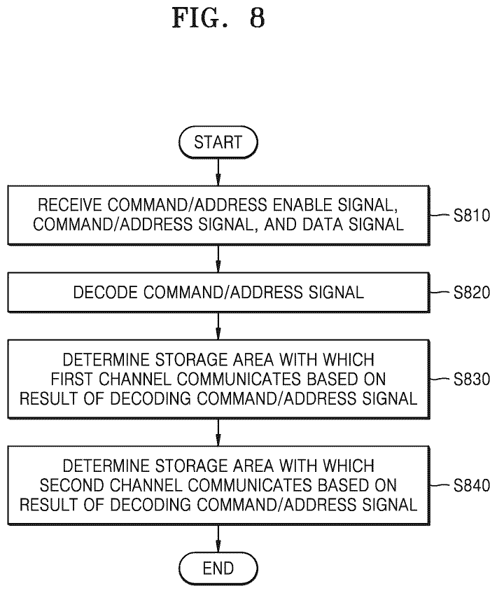

FIG. 8 is a flowchart of a process for determining storage areas with which a first channel and a second channel communicate in a method of operating a storage device according to an example embodiment.

Referring to FIGS. 2, and 8, the buffer chip 120 of the storage device 100 according to an example embodiment may receive the chip enable signal CE, the command/address signal CA, and the data signal DQ (S810).

For example, the buffer chip 120 of the storage device 100 may receive the command/address signal CA through the first channel 121, and may receive the data signal DQ through the second channel 123.

In some example embodiments, when the buffer chip 120 receives the chip enable signal CE, the command/address signal CA, and the data signal DQ, the storage device 100 may decode the command/address signal CA (S820).

The storage device 100 according to an example embodiment may include at least one decoder 122. For example, since the first channel 121 includes the decoder 122, the storage device 100 may include the decoder 122. The decoder 122 according to an example embodiment may decode the command/address signal CA.

In some example embodiments, when the command/address signal CA is decoded, the storage device 100 may determine a storage area with which the first channel 121 communicates based on the result of decoding the command/address signal CA (S830).

The storage device 100 according to an example embodiment may determine a storage area with which the first channel 121 communicates based on the result of decoding the command/address signal CA. For example, when the first channel 121 is activated by the chip enable signal CE, the storage device 100 may decode the command/address signal CA and may determine the first storage area 131 based on the decoding result. The command/address signal CA according to an example embodiment may include information about the storage area to which the command/address signal CA is to be transmitted.

In addition, when the command/address signal CA is decoded, the storage device 100 according to an example embodiment may determine a storage area with which the second channel 123 communicates based on the result of decoding the command/address signal CA (S840).

The storage device 100 according to an example embodiment may transmit the data signal DQ to the second storage area 132 based on the result of decoding the command/address signal CA. For example, based on the result of decoding the command/address signal CA, the storage device 100 may determine the first storage area 131 and the second storage area 132 and may determine a storage area to which the command/address signal CA is not transmitted as the second storage area 132. The command/address signal CA according to an example embodiment may include path information of the data signal DQ.

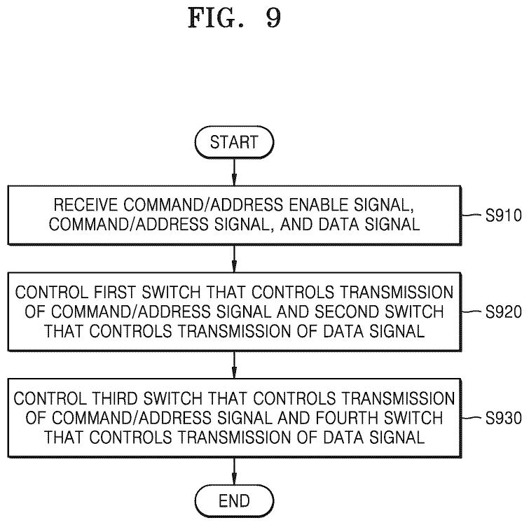

FIG. 9 is a flowchart of a process for controlling transmission of a command/address signal and a data signal in a method of operating a storage device according to an example embodiment.

Referring to FIGS. 3A and 9, the buffer chip 120 of the storage device 100 according to an example embodiment may receive the chip enable signal CE, the command/address signal CA, and the data signal DQ (S910).

For example, the buffer chip 120 of the storage device 100 may receive the command/address signal CA through the first channel 121, and may receive the data signal DQ through the second channel 123.

In some example embodiments, when the chip enable signal CE, the command/address signal CA, and the data signal DQ are received by the buffer chip 120, the storage device 100 may control the first switch 121c that controls transmission of the command/address signal CA and the second switch 121d that controls transmission of the data signal DQ (S920).

For example, when the first storage area 131 is determined as an area to which the command/address signal CA is transmitted based on the decoding result, the storage device 100 may transmit the command/address signal CA to the first storage area 131 by closing the first switch 121c. In some example embodiments, when the first switch 121c is closed, the path for transmitting the command/address signal CA to the first storage area 131 may be the selection path Sel. In another example, when the first storage area 131 is determined as an area to which the data signal DQ is not transmitted based on the decoding result, the storage device 100 may not transmit the data signal DQ to the first storage area 131 by opening the second switch 121d.

In addition, when the chip enable signal CE, the command/address signal CA, and the data signal DQ are received by the buffer chip 120, the storage device 100 according to an example embodiment may control the third switch 123c that controls transmission of the command/address signal CA and the fourth switch 123d that controls transmission of the data signal DQ (S930).

For example, when the second storage area 132 is determined as an area to which the command/address signal CA is not transmitted based on the decoding result, the storage device 100 may not transmit the command/address signal CA to the second storage area 132 by opening the third switch 123c. For example, when the second storage area 132 is determined as an area to which the data signal DQ is transmitted based on the decoding result, the storage device 100 may transmit the data signal DQ to the second storage area 132 by closing the fourth switch 123d. In some example embodiments, when the fourth switch 123d is closed, the path for transmitting the data signal DQ to the second storage area 132 may be the selection path Sel.

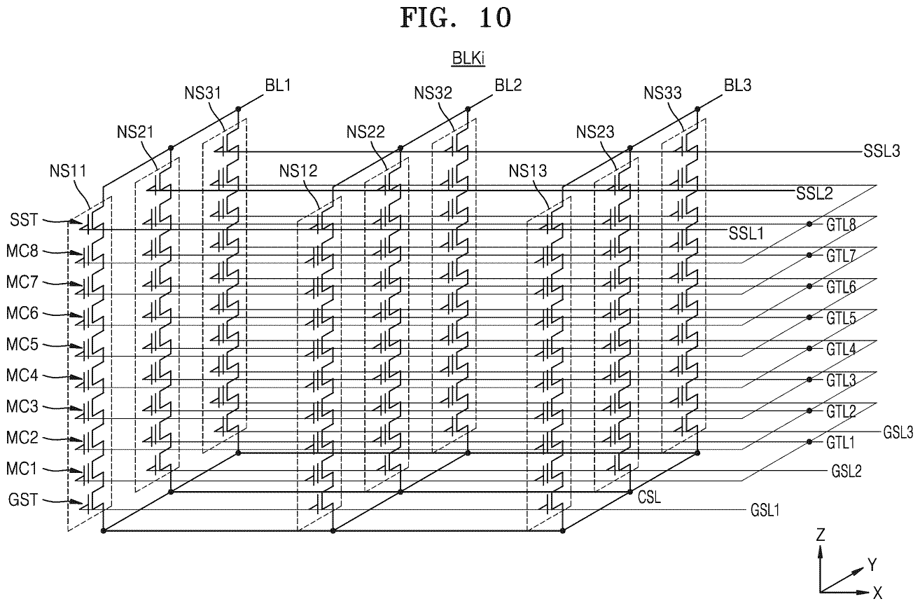

FIGS. 10 to 12 are diagrams illustrating a three-dimensional V-NAND structure that can be applied to a memory device according to an example embodiment.

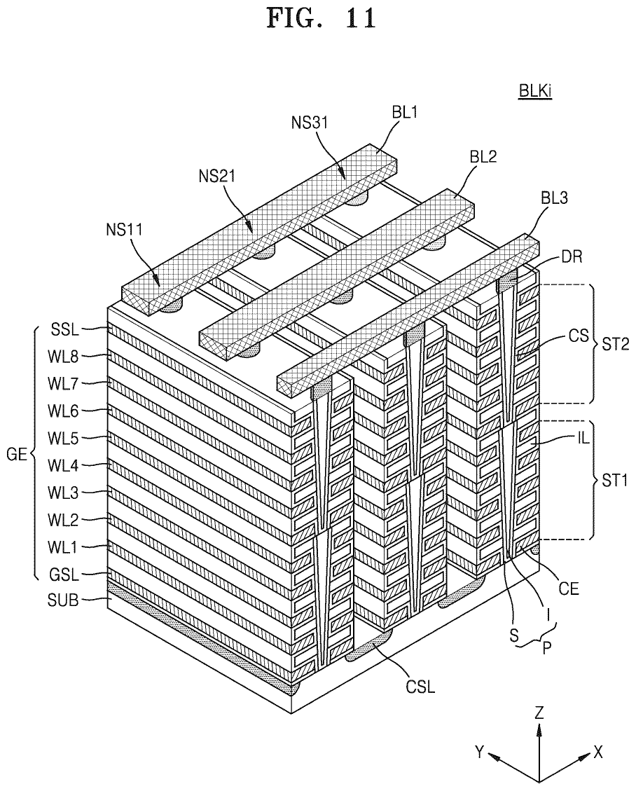

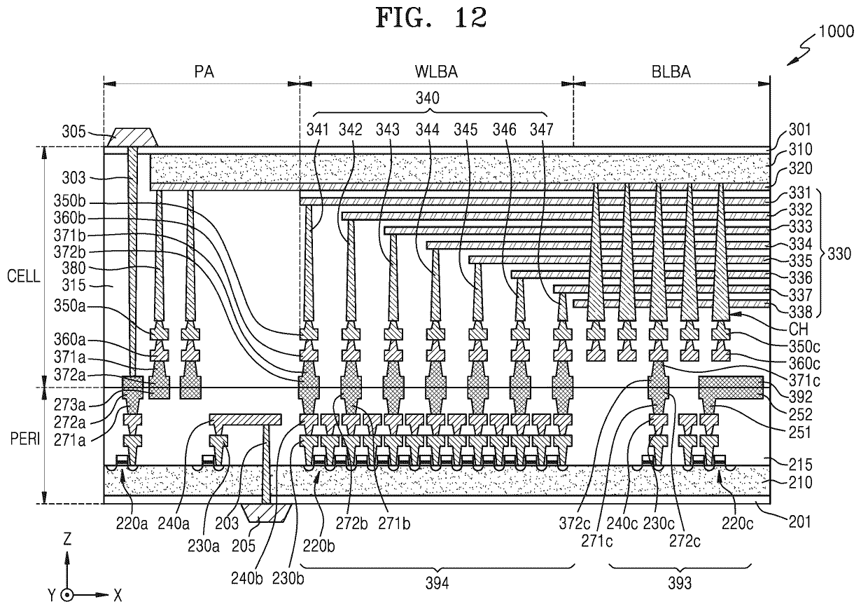

Non-volatile memory 1000 applicable to the memory device 130 of FIG. 1 may include a plurality of memory blocks. FIGS. 10 and 11 illustrate the structure of one memory block BLKi among a plurality of memory blocks, and FIG. 12 illustrates an implementation example of the non-volatile memory 1000.

Referring to FIG. 10, the memory block BLKi may include a plurality of memory NAND strings NS11 to NS33 connected between bit lines BL1, BL2, and BL3 and a common source line CSL. Each of the plurality of memory NAND strings NS11 to NS33 may include a string select transistor SST, a plurality of memory cells MC1 to MC8, and a ground select transistor GST. For brevity of the drawing, it is illustrated that each of the plurality of memory NAND strings NS11 to NS33 includes eight memory cells MC1 to MC8 in FIG. 10, but example embodiments are not limited thereto.

The string select transistor SST may be connected to the corresponding string select line SSL1, SSL2, and SSL3. The plurality of memory cells MC1 to MC8 may be connected to gate lines GTL1 to GTL8, respectively. The gate lines GTL1 to GTL8 may correspond to word lines, and some of the gate lines GTL1 to GTL8 may correspond to dummy word lines. The ground select transistor GST may be connected to the corresponding ground select line GSL1, GSL2, and GSL3. The string select transistor SST may be connected to the corresponding bit line BL1, BL2, and BL3, and the ground select transistor GST may be connected to the common source line CSL.

The gate line (e.g., GTL1) of the same height may be connected in common, and the ground selection lines GSL1, GSL2, GSL3 may be separated from the string selection lines SSL1, SSL2, and SSL3. In FIG. 10, it is illustrated that the memory block BLKi is connected to eight gate lines GTL1 to GTL8 and three bit lines BL1, BL2, and BL3, but example embodiments are not limited thereto.

Referring to FIG. 11, the memory block BLKi is formed in a vertical direction with respect to a substrate SUB. Memory cells constituting the memory NAND strings NS11 to NS33 are stacked on a plurality of semiconductor layers.

On the substrate SUB, the common source lines CSL extending in a first direction (Y direction) are provided. In an area of the substrate SUB between two adjacent common source lines CSL, a plurality of insulating films IL extending in the first direction (Y direction) may be sequentially provided in a third direction (Z direction), and the plurality of insulating films IL may be spaced apart from each other by a specific distance in the third direction (Z direction). In the area of the substrate SUB between two adjacent common source lines CSL, a plurality of pillars P are sequentially arranged in the first direction (Y direction) and pass through the plurality of insulating films IL in the third direction (Z direction). The plurality of pillars P may pass through the plurality of insulating films IL and contact the substrate SUB. A surface layer S of each pillar P may include a silicon material doped into a first conductivity type and may function as a channel region.

An inner layer I of each pillar P may include an insulating material, such as silicon oxide or an air gap. In the area between two adjacent common source lines CSL, a charge storage layer CS is provided along the exposed surfaces of the insulating films IL, the pillars P, and the substrate SUB. The charge storage layer CS may include a gate insulating layer (also referred to as a ‘tunneling insulating layer’), a charge trap layer, and a blocking insulating layer. In addition, in the area between two adjacent common source lines CSL, a gate electrode GE, such as select lines GSL and SSL and word lines WL1 to WL8, is provided on the exposed surface of the charge storage layer CS. Drains or drain contacts DR may be provided on the plurality of pillars P, respectively. The bit lines BL1 to BL3 extending in a second direction (X direction) and spaced apart from each other by a specific distance in the first direction (Y direction) may be provided on the drain contacts DR.

As shown in FIG. 11, each memory NAND string NS11 to NS33 may be implemented in a structure in which a first memory stack ST1 and a second memory stack ST2 are stacked. The first memory stack ST1 is connected to the common source line CSL, the second memory stack ST2 is connected to the bit lines BL1 to BL3, and the first memory stack ST1 and the second memory stack ST2 are stacked to share channel holes with each other.

FIG. 12 is a diagram illustrating a memory device 400 according to an example embodiment.

Referring to FIG. 12, a memory device 400 may have a chip-to-chip (C2C) structure. The C2C structure may refer to a structure formed by manufacturing an upper chip including a cell region CELL on a first wafer, manufacturing a lower chip including a peripheral circuit region PERI on a second wafer, separate from the first wafer, and then bonding the upper chip and the lower chip to each other. In some example embodiments, the bonding process may include a method of electrically connecting a bonding metal formed on an uppermost metal layer of the upper chip and a bonding metal formed on an uppermost metal layer of the lower chip. For example, when the bonding metals may include copper (Cu) using a Cu-to-Cu bonding, but example embodiments are not limited thereto. For example, the bonding metals may also be formed of aluminum (Al) or tungsten (W).

Each of the peripheral circuit region PERI and the cell region CELL of the memory device 400 may include an external pad bonding area PA, a word line bonding area WLBA, and a bit line bonding area BLBA.

The peripheral circuit region PERI may include a first substrate 210, an interlayer insulating layer 215, a plurality of circuit elements 220a, 220b, and 220c formed on the first substrate 210, first metal layers 230a, 230b, and 230c respectively connected to the plurality of circuit elements 220a, 220b, and 220c, and second metal layers 240a, 240b, and 240c formed on the first metal layers 230a, 230b, and 230c. In an example embodiment, the first metal layers 230a, 230b, and 230c may be formed of tungsten having relatively high electrical resistivity (or having high electrical resistivity), and the second metal layers 240a, 240b, and 240c may be formed of copper having relatively low electrical resistivity (or having low electrical resistivity).

In an example embodiment illustrate in FIG. 12, although only the first metal layers 230a, 230b, and 230c and the second metal layers 240a, 240b, and 240c are shown and described, example embodiments are not limited thereto, and one or more additional metal layers may be further formed on the second metal layers 240a, 240b, and 240c. At least a portion of the one or more additional metal layers formed on the second metal layers 240a, 240b, and 240c may be formed of aluminum or the like having a lower electrical resistivity than those of copper forming the second metal layers 240a, 240b, and 240c.

The interlayer insulating layer 215 may be disposed on the first substrate 210 and cover the plurality of circuit elements 220a, 220b, and 220c, the first metal layers 230a, 230b, and 230c, and the second metal layers 240a, 240b, and 240c. The interlayer insulating layer 215 may include an insulating material such as silicon oxide, silicon nitride, or the like.

Lower bonding metals 271b and 272b may be formed on the second metal layer 240b in the word line bonding area WLBA. In the word line bonding area WLBA, the lower bonding metals 271b and 272b in the peripheral circuit region PERI may be electrically bonded to upper bonding metals 371b and 372b of the cell region CELL. The lower bonding metals 271b and 272b and the upper bonding metals 371b and 372b may be formed of aluminum, copper, tungsten, or the like, but example embodiments are not limited thereto. Further, the upper bonding metals 371b and 372b in the cell region CELL may be referred as first metal pads and the lower bonding metals 5271b and 5272b in the peripheral circuit region PERI may be referred as second metal pads.

The cell region CELL may include at least one memory block. The cell region CELL may include a second substrate 310 and a common source line 320. On the second substrate 310, a plurality of word lines 331 to 338 (e.g., 330) may be stacked in a direction (a Z-axis direction), perpendicular to an upper surface of the second substrate 310. At least one string select line and at least one ground select line may be arranged on and below the plurality of word lines 330, respectively, and the plurality of word lines 330 may be disposed between the at least one string select line and the at least one ground select line.

In the bit line bonding area BLBA, a channel structure CH may extend in a direction (a Z-axis direction), perpendicular to the upper surface of the second substrate 310, and pass through the plurality of word lines 330, the at least one string select line, and the at least one ground select line. The channel structure CH may include a data storage layer, a channel layer, a buried insulating layer, and the like, and the channel layer may be electrically connected to a first metal layer 350c and a second metal layer 360c. For example, the first metal layer 350c may be a bit line contact, and the second metal layer 360c may be a bit line. In an example embodiment, the bit line 360c may extend in a first direction (a Y-axis direction), parallel to the upper surface of the second substrate 310.

In an example embodiment illustrated in FIG. 12, an area in which the channel structure CH, the bit line 360c, and the like are disposed may be defined as the bit line bonding area BLBA. In the bit line bonding area BLBA, the bit line 360c may be electrically connected to the circuit elements 220c providing a page buffer 393 in the peripheral circuit region PERI. The bit line 360c may be connected to upper bonding metals 371c and 372c in the cell region CELL, and the upper bonding metals 371c and 372c may be connected to lower bonding metals 271c and 272c connected to the circuit elements 220c of the page buffer 393.

In the word line bonding area WLBA, the plurality of word lines 330 may extend in a second direction (an X-axis direction), parallel to the upper surface of the second substrate 310 and perpendicular to the first direction, and may be connected to a plurality of cell contact plugs 341 to 347 (e.g., 340). The plurality of word lines 330 and the plurality of cell contact plugs 340 may be connected to each other in pads provided by at least a portion of the plurality of word lines 330 extending in different lengths in the second direction. A first metal layer 350b and a second metal layer 360b may be connected to an upper portion of the plurality of cell contact plugs 340 connected to the plurality of word lines 330, sequentially. The plurality of cell contact plugs 340 may be connected to the peripheral circuit region PERI by the upper bonding metals 371b and 372b of the cell region CELL and the lower bonding metals 271b and 272b of the peripheral circuit region PERI in the word line bonding area WLBA.

The plurality of cell contact plugs 340 may be electrically connected to the circuit elements 220b forming a row decoder 394 in the peripheral circuit region PERI. In an example embodiment, operating voltages of the circuit elements 220b of the row decoder 394 may be different than operating voltages of the circuit elements 220c forming the page buffer 393. For example, operating voltages of the circuit elements 220c forming the page buffer 393 may be greater than operating voltages of the circuit elements 220b forming the row decoder 394.

A common source line contact plug 380 may be disposed in the external pad bonding area PA. The common source line contact plug 380 may be formed of a conductive material such as a metal, a metal compound, polysilicon, or the like, and may be electrically connected to the common source line 320. A first metal layer 350a and a second metal layer 360a may be stacked on an upper portion of the common source line contact plug 380, sequentially. For example, an area in which the common source line contact plug 380, the first metal layer 350a, and the second metal layer 360a are disposed may be defined as the external pad bonding area PA.

Input-output pads 205 and 305 may be disposed in the external pad bonding area PA. Referring to FIG. 12, a lower insulating film 201 covering a lower surface of the first substrate 210 may be formed below the first substrate 210, and a first input-output pad 205 may be formed on the lower insulating film 201. The first input-output pad 205 may be connected to at least one of the plurality of circuit elements 220a, 220b, and 220c disposed in the peripheral circuit region PERI through a first input-output contact plug 203, and may be separated from the first substrate 210 by the lower insulating film 201. In addition, a side insulating film may be disposed between the first input-output contact plug 203 and the first substrate 210 to electrically separate the first input-output contact plug 203 and the first substrate 210.

Referring to FIG. 12, an upper insulating film 301 covering the upper surface of the second substrate 310 may be formed on the second substrate 310, and a second input-output pad 305 may be disposed on the upper insulating layer 301. The second input-output pad 305 may be connected to at least one of the plurality of circuit elements 220a, 220b, and 220c disposed in the peripheral circuit region PERI through a second input-output contact plug 303. In some example embodiments, the second input-output pad 305 is electrically connected to a circuit element 220a.

According to some example embodiments, the second substrate 310 and the common source line 320 may not be disposed in an area in which the second input-output contact plug 303 is disposed. Also, the second input-output pad 305 may not overlap the word lines 330 in the third direction (the Z-axis direction). Referring to FIG. 12, the second input-output contact plug 303 may be separated from the second substrate 310 in a direction, parallel to the upper surface of the second substrate 310, and may pass through the interlayer insulating layer 315 of the cell region CELL to be connected to the second input-output pad 305.

According to some example embodiments, the first input-output pad 205 and the second input-output pad 305 may be selectively formed. For example, the memory device 400 may include only the first input-output pad 205 disposed on the first substrate 210 or the second input-output pad 305 disposed on the second substrate 310. Alternatively, the memory device 400 may include both the first input-output pad 205 and the second input-output pad 305.

A metal pattern provided on an uppermost metal layer may be provided as a dummy pattern or the uppermost metal layer may be absent, in each of the external pad bonding area PA and the bit line bonding area BLBA, respectively included in the cell region CELL and the peripheral circuit region PERI.

In the external pad bonding area PA, the memory device 400 may include a lower metal pattern 273a, corresponding to an upper metal pattern 372a formed in an uppermost metal layer of the cell region CELL, and having the same cross-sectional shape as the upper metal pattern 372a of the cell region CELL so as to be connected to each other, in an uppermost metal layer of the peripheral circuit region PERI. In the peripheral circuit region PERI, the lower metal pattern 273a formed in the uppermost metal layer of the peripheral circuit region PERI may not be connected to a contact. Similarly, in the external pad bonding area PA, an upper metal pattern 372a, corresponding to the lower metal pattern 273a formed in an uppermost metal layer of the peripheral circuit region PERI, and having the same shape as a lower metal pattern 273a of the peripheral circuit region PERI, may be formed in an uppermost metal layer of the cell region CELL.

The lower bonding metals 271b and 272b may be formed on the second metal layer 240b in the word line bonding area WLBA. In the word line bonding area WLBA, the lower bonding metals 271b and 272b of the peripheral circuit region PERI may be electrically connected to the upper bonding metals 371b and 372b of the cell region CELL by a Cu-to-Cu bonding.

Further, in the bit line bonding area BLBA, an upper metal pattern 392, corresponding to a lower metal pattern 252 formed in the uppermost metal layer of the peripheral circuit region PERI, and having the same cross-sectional shape as the lower metal pattern 252 of the peripheral circuit region PERI, may be formed in an uppermost metal layer of the cell region CELL. A contact may not be formed on the upper metal pattern 392 formed in the uppermost metal layer of the cell region CELL.

In an example embodiment, corresponding to a metal pattern formed in an uppermost metal layer in one of the cell region CELL and the peripheral circuit region PERI, a reinforcement metal pattern having the same cross-sectional shape as the metal pattern may be formed in an uppermost metal layer in the other one of the cell region CELL and the peripheral circuit region PERI. A contact may not be formed on the reinforcement metal pattern.

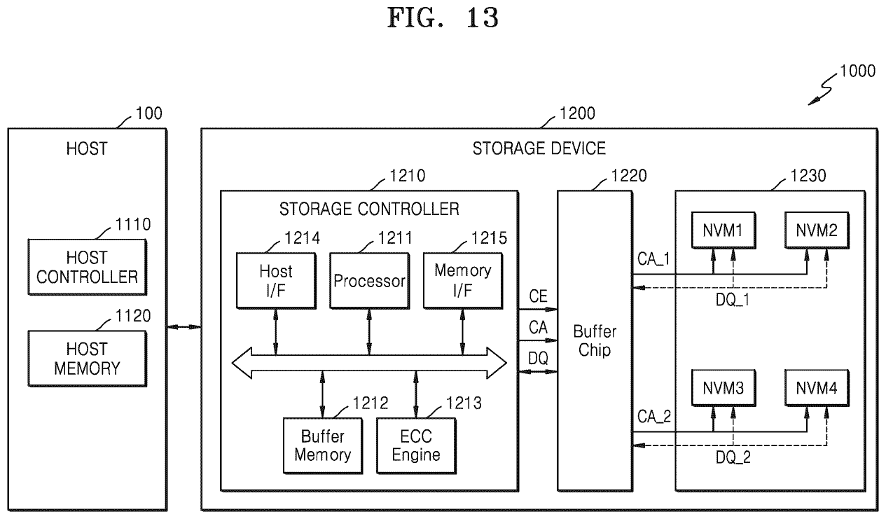

FIG. 13 is a block diagram of a storage system according to an example embodiment.

Referring to FIG. 13, a storage system 1000 may include a host device 1100 and a storage device 1200. In an example embodiment, the storage device 1200 may include the storage device 100 described with reference to FIGS. 1 to 13. The storage device 1200 may include a high-capacity storage medium, such as a solid state drive (SSD). The storage device 1200 may be included in one of information processing devices configured to process various information and store the processed information, such as a personal computer, a laptop, a server, a workstation, a smartphone, a tablet PC, a digital camera, a black box, and the like. However, example embodiments are not limited thereto. The storage device 1200 may be implemented in various forms and may be included in various devices or various systems.

In an example embodiment, the host device 1100 may include a host controller 1110 and host memory 1120. The host memory 1120 may function as buffer memory to temporarily store data to be transmitted to the storage device 1200 or data transmitted from the storage device 1200.

According to an example embodiment, the host controller 1110 and the host memory 1120 may be implemented as separate semiconductor chips. Alternatively, in some example embodiments, the host controller 1110 and the host memory 1120 may be integrated into the same semiconductor chip. As an example, the host controller 1110 may be one of multiple modules included in an application processor, wherein the application processor may be implemented as a system on chip (SoC). Additionally, the host memory 1120 may include embedded memory provided within the application processor, or may include non-volatile memory or a memory module arranged outside the application processor.

The host controller 1110 may store data (e.g., write data) in the buffer area of the host memory 1120 in the non-volatile memory device 1230 or may manage the operation of storing data (e.g., read data) of the non-volatile memory device 1230 in the buffer area thereof.

The host device 1100 may be configured to control the storage device 1200. For example, the host device 1100 may store data in the storage device 1200 or read data stored in the storage device 1200 based on a preset interface. In an example embodiment, the preset interface may include a non-volatile memory express (NVMe) interface. However, example embodiments are not limited thereto. The preset interface may include at least one of various interfaces, such as advanced technology attachment (ATA), serial ATA (SATA), external SATA (e-SATA), small computer small interface (SCSI), serial attached SCSI (SAS), peripheral component interconnect (PCI), PCI express (PCIe), universal flash storage (UFS), IEEE 1394, universal serial bus (USB), secure digital (SD) card, multi-media card (MMC), embedded MMC (eMMC), embedded UFS (eUFS), compact flash (CF) card interface, and compute eXpress link (CXL) interface.

The storage device 1200 may include a storage controller 1210, a buffer chip 1220, and a non-volatile memory device 1230. The storage controller 1210 may include the memory controller 110 described with reference to FIGS. 1 to 12. The buffer chip 1220 may include the buffer chip 120 described with reference to FIGS. 1 to 12. The non-volatile memory device 1230 may include the memory device 130 described with reference to FIGS. 1 to 12.

The storage controller 1210 may operate under the control of the host device 1100. For example, the storage controller 1210 may store data in the non-volatile memory device 1230 or provide data stored in the non-volatile memory device 1230 to the host device 1100 under the control of the host device 1100. In an example embodiment, the storage controller 1210 may perform various management operations under the control of the host device 1100. In an example embodiment, the various management operations may include setting various information of the storage device 1200 or providing various information set in the storage device 1200 to the host device 1100.

The storage controller 1210 may include a processor 1211, buffer memory 1212, an error correction code (ECC) engine 1213, a host interface circuit 1214, and a memory interface circuit 1215. The processor 1211 may control overall operations of the storage controller 1210. For example, the processor 1211 may run an operating system or firmware for driving the storage controller 1210. The processor 1211 may generate commands and addresses to control the non- volatile memory device 1230 based on a request from the host device 1100.

The buffer memory 1212 may temporarily store data to be stored in the non-volatile memory device 1230 or data read from the non-volatile memory device 1230. The buffer memory 1212 may be configured to store various information necessary for the storage controller 1210 to operate. For example, the buffer memory 1212 may be configured to store a map table for accessing the non-volatile memory device 1230. In an example embodiment, the buffer memory 1212 may include random-access memory. For example, the buffer memory 1212 may include static random-access memory or dynamic random-access memory.

The ECC engine 1213 may perform ECC encoding on user data to be stored in the non-volatile memory device 1230 and generate parity data. The generated parity data may be stored in the non-volatile memory device 1230 along with the user data. The ECC engine 1213 may be configured to perform ECC decoding based on the parity data and the user data read from the non-volatile memory device 1230 to correct errors in the user data.

The host interface circuit 1214 may be configured to communicate with the host device 1100. In an example embodiment, the host interface circuit 1214 may be configured to comply with a preset interface, communication protocol, or communication standard between the host device 1100 and the storage device 1200.

The memory interface circuit 1215 may be configured to access the non-volatile memory device 1230. For example, the memory interface circuit 1215 may be configured to access the non-volatile memory device 1230 based on commands and addresses for controlling the non-volatile memory device 1230 generated by the processor 1211. In an example embodiment, the memory interface circuit 1215 may communicate with the non-volatile memory device 1230 based on an interface or a protocol determined based on a standard or determined by a manufacturer. In an example embodiment, the interface or protocol described above may include a toggle interface or open NAND flash interface (ONFI).

The non-volatile memory device 1230 may operate under the control of the storage controller 1210. The non-volatile memory device 1230 may include a plurality of non-volatile memories NVM1 to NVM4. However, example embodiments are not limited thereto. The number of non-volatile memories may decrease or increase, depending on implementation.

In an example embodiment, the plurality of non-volatile memories NVM1 to NVM4 included in the non-volatile memory device 1230 may communicate with the storage controller 1210 through a plurality of channels and form a plurality of ways. For example, each of the plurality of non-volatile memories NVM1 to NVM4 may include a memory die. In an example embodiment, the non-volatile memory device 1230 may be configured based on NAND flash memory. However, example embodiments are not limited thereto. The non-volatile memory device 1230 may be configured based on at least one of various non-volatile memory devices, such as a phase-change memory device, a ferroelectric memory device, a magnetic memory device, and a resistive memory device. For example, the first storage area may include the first non-volatile memory NVM1 and the second non-volatile memory NVM2, and the second storage area may include the third non-volatile memory NVM3 and the fourth non-volatile memory NVM4.

In an example embodiment, the buffer chip 1220 may receive the chip enable signal CE and the command/address signal CA from the storage controller 1210. The buffer chip 1220 may receive the data signal DQ from the storage controller 1210 or transmit the data signal DQ to the storage controller 1210. In an example embodiment, the buffer chip 1220 may receive the command/address signal CA from the storage controller 1210 through command/address lines. The buffer chip 1220 may transmit and receive the data signal DQ to and from the storage controller 1210 through data lines. The command/address lines and the data lines may include divided lines. The command/address lines and the data lines may include different lines. The command/address lines and the data lines may include separate lines.

In an example embodiment, the chip enable signal CE may not control the data signal DQ. The chip enable signal CE may control the command/address signal CA. The command/address signal CA may be activated based on the chip enable signal CE. For example, chip enable signal CE may include a command/address chip enable signal.

In an example embodiment, the first non-volatile memory NVM1 and the second non-volatile memory NVM2 may be connected to first command/address lines and first data lines. The third non-volatile memory NVM3 and the fourth non-volatile memory NVM4 may be connected to second command/address lines and second data lines.

The first non-volatile memory NVM1 and the second non-volatile memory NVM2 may communicate with the buffer chip 1220 through the first command/address lines and the first data lines. The third non-volatile memory NVM3 and the fourth non-volatile memory NVM4 may communicate with the buffer chip 1220 through the second command/address lines and the second data lines. However, example embodiments are not limited thereto. The number of non-volatile memories sharing command/address lines and data lines may decrease or increase, depending on implementation.

In an example embodiment, the buffer chip 1220 may transmit a first command/address signal CA_1 to the first non-volatile memory NVM1. The buffer chip 1220 may transmit and receive the first data signal DQ_1 to and from the first non-volatile memory NVM1. The buffer chip 1220 may transmit the first command/address signal CA_1 to the first non-volatile memory NVM1 through the first command/address lines. The buffer chip 1220 may transmit and receive the first data signal DQ_1 to and from the first non-volatile memory NVM1 through the first data lines.

In an example embodiment, the buffer chip 1220 may transmit the first command/address signal CA_1 to the second non-volatile memory NVM2. The buffer chip 1220 may transmit and receive the first data signal DQ_1 to and from the second non-volatile memory NVM2. The buffer chip 1220 may transmit the first command/address signal CA_1 to the second non-volatile memory NVM2 through the first command/address lines. The buffer chip 1220 may transmit and receive the first data signal DQ_1 to and from the second non-volatile memory NVM2 through the first data lines.

In an example embodiment, the buffer chip 1220 may transmit the second command/address signal CA_2 to the third non-volatile memory NVM3. The buffer chip 1220 may transmit and receive the second data signal DQ_2 to and from the third non-volatile memory NVM3. The buffer chip 1220 may transmit the second command/address signal CA_2 to the third non-volatile memory NVM3 through the second command/address lines. The buffer chip 1220 may transmit and receive the second data signal DQ_2 to and from the third non-volatile memory NVM3 through the second data lines.

In an example embodiment, the buffer chip 1220 may transmit the second command/address signal CA_2 to the fourth non-volatile memory NVM4. The buffer chip 1220 may transmit and receive the second data signal DQ_2 to and from the fourth non-volatile memory NVM4. The buffer chip 1220 may transmit the second command/address signal CA_2 to the fourth non-volatile memory NVM4 through the second command/address lines. The buffer chip 1220 may transmit and receive the second data signal DQ_2 to and from the fourth non-volatile memory NVM4 through the second data lines.

In an example embodiment, the first command/address lines and the first data lines may include separate lines. The second command/address lines and second data lines may include separate lines. The second command/address lines and the first command/address lines may include separate lines. The second data lines and the first data lines may include separate lines.

In an example embodiment, the buffer chip 1220 is capable of two-way communication of command/address signals and data signals independently and simultaneously with other non-volatile memories. While the buffer chip 1220 transmits and receives data to and from the first storage area through the first data lines, the buffer chip 1220 may transmit a command/address to the second storage area through the second command/address lines. Alternatively, while the buffer chip 1220 transmits a command/address to the first storage area through the first command/address lines, the buffer chip 1220 may transmit and receive data to and from the second storage area through the second data lines. For example, while the buffer chip 1220 communicates with either the first non-volatile memory NVM1 or the second non-volatile memory NVM2 through the first data lines, the buffer chip 1220 may communicate with either the third non-volatile memory NVM3 or the fourth non-volatile memory NVM4 through second command/address lines.

For example, while the buffer chip 1220 transmits the first command/address signal CA_1 to the first non-volatile memory NVM1 through the first command/address lines, the buffer chip 1220 may receive the second data signal DQ_2 from the third non-volatile memory NVM2 through the second data lines. For example, while the buffer chip 1220 transmits data to the first non-volatile memory NVM1 through the first data lines, the buffer chip 1220 may transmit a command/address to the third non-volatile memory NVM3 through the second command/address lines.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to example embodiments thereof, it will be understood that various changes in form and details may be made therein without departing from the spirit and scope of the following claims.

1. A storage device comprising:
a memory controller configured to generate at least one of a chip enable signal and a command/address signal;
a buffer chip configured to receive the chip enable signal, the command/address signal, and a data signal from the memory controller; and
a memory device including at least one storage area, the at least one storage area configured to perform at least one of a write operation and a read operation, based on the command/address signal and the data signal received by the buffer chip,
wherein the buffer chip comprises a first channel configured to receive the chip enable signal or the command/address signal, and a second channel configured to receive the data signal,
wherein the first channel and the second channel are configured to transmit signals received through separate paths to respective ones of the at least one storage area.

2. The storage device of claim 1, wherein the buffer chip further comprises a decoder for decoding the command/address signal, and
wherein the buffer chip is configured to determine a first storage area with which the first channel communicates based on a result of decoding the command/address signal.

3. The storage device of claim 2, wherein the buffer chip is configured to determine a second storage area with which the second channel communicates based on a result of decoding the command/address signal.

4. The storage device of claim 1, wherein the buffer chip is configured to communicate the data signal with a second storage area through the second channel while the command/address signal is transmitted to a first storage area through the first channel.

5. The storage device of claim 1, wherein the memory device comprises a plurality of chips, and
wherein the buffer chip is configured to independently exchange signals with each of the plurality of chips.

6. The storage device of claim 1, wherein the first channel comprises a first switch configured to control transmission of the command/address signal and a second switch configured to control transmission of the data signal, and
wherein the second channel comprises a third switch configured to control transmission of the command/address signal and a fourth switch configured to control transmission of the data signal.

7. The storage device of claim 1, wherein the first channel is configured to transmit the command/address signal to a plurality of dies included in the memory device.

8. A method of operating a storage device, the method comprising:
generating at least one of a chip enable signal and a command/address signal;
receiving the chip enable signal, the command/address signal, and a data signal; and
performing at least one of a write operation and a read operation, based on the received command/address signal and data signal,
wherein the receiving of the chip enable signal, the command/address signal, and the data signal includes
receiving the chip enable signal or the command/address signal through a first channel,
receiving the data signal through a second channel that is different from the first channel, and
transmitting the received signals to respective ones of at least one storage area.

9. The method of claim 8, wherein the receiving of the chip enable signal, the command/address signal, and the data signal further comprises decoding the command/address signal.

10. The method of claim 9, wherein the decoding of the command/address signal comprises determining a first storage area with which the first channel communicates based on a result of decoding the command/address signal.

11. The method of claim 9, wherein the decoding of the command/address signal further comprises determining a second storage area with which the second channel communicates based on a result of decoding the command/address signal.

12. The method of claim 8, wherein the receiving of the chip enable signal, the command/address signal, and the data signal further comprises communicating the data signal with a second storage area through the second channel while the command/address signal is transmitted to a first storage area through the first channel.

13. The method of claim 8, wherein the receiving of the chip enable signal, the command/address signal, and the data signal further comprises independently exchanging signals with each of a plurality of chips of a memory device.

14. The method of claim 8, wherein the receiving of the chip enable signal, the command/address signal, and the data signal further comprises
controlling a first switch configured to control transmission of the command/address signal and a second switch configured to control transmission of the data signal; and
controlling a third switch configured to control transmission of the command/address signal and a fourth switch configured to control transmission of the data signal.

15. The method of claim 8, wherein the receiving of the chip enable signal, the command/address signal, and the data signal further comprises transmitting the command/address signal to a plurality of dies included in a memory device.

16. A buffer chip comprising:
a first channel configured to receive a chip enable signal or the command/address signal; and
a second channel configured to receive a data signal,
wherein the first channel and the second channel are further configured to transmit signals received through separate paths to respective ones of at least one storage area.

17. The buffer chip of claim 16, wherein the first channel further comprises a decoder for decoding the command/address signal, and
wherein the buffer chip is configured to determine a first storage area with which the first channel communicates based on a result of decoding the command/address signal.

18. The buffer chip of claim 17, wherein the first channel is configured to determine a second storage area with which the second channel communicates based on a result of decoding the command/address signal.

19. The buffer chip of claim 16, wherein the buffer chip is configured to communicate the data signal with a second storage area through the second channel while the command/address signal is transmitted to a first storage area through the first channel.

20. The buffer chip of claim 16, wherein the first channel and the second channel are configured to independently exchange signals with each of a plurality of chips included in a memory device.

21-22. (canceled)
